(19) United States
(12) Patent Application Publication
(10) Pub. No.: US 2024/0206105 A1
(43) Pub. Date: Jun. 20, 2024

(54) MOUNTING STRUCTURE OF RACKMOUNT UNIT AND RACK-MOUNT MOUNTING MEMBER

(71) Applicant: THAMWAY CO., LTD

(72) Inventor: Jun MOCHIZUKI, FUJI (JP)

(73) Assignee: THAMWAY CO., LTD, FUJI (JP)

(21) Appl. No.: 18/492,840

(22) Filed: Oct. 24, 2023

(30) Foreign Application Priority Data
Dec. 19, 2022 (JP) 2022-201862

(51) Int. Cl. H05K 7/18

(52) U.S. Cl. CPC H05K 7/18

(57) ABSTRACT

A mounting structure of a rack-mount unit for accommodating a unit in a rack mount, by loading of the unit from a front opening of the rack mount, and by engagement and fastening of fastening holes formed in the perpendicular direction of flanges provided at the both ends in the lengthwise direction of the front surface of the unit, with fastening holes formed in the perpendicular direction of a pair of rails elongating in the perpendicular direction and disposed on the both sides on the front side of the rack mount. One end of a plate-shaped part elongating from the flange toward a body side panel of the unit is connected to the flange, and another end of the plate-shaped part is connected to the body side panel, of which hypotenuse is the plate-shaped part, and of which adjacent side is the body side panel of the unit.

### TECHNICAL FIELD

The present invention relates to a mounting structure of rack mounting unit, and a rack-mount mounting member.

### BACKGROUND ART

For the purpose of accommodating a unit in a rack mount which is capable of accommodating a plurality of low-profile units, there is a fixing method, in which the both ends of the front surface of the unit is fastened by bolts onto a pair of rails, which are elongating in the perpendicular direction and disposed at the both ends in the horizontal direction on the front side in the interior of a rack frame (for example, see Patent Literature 1).

Moreover, as illustrated in FIG. 23, there is another method, in which a unit is placed on angle mount brackets provided in the interior of a rack frame.

### CITATION LIST

### Patent Literature

Patent Literature 1: JP 2002-204090 A

### SUMMARY OF INVENTION

### Technical Problem

According to a mounting structure so-called “cantilever beam structure,” in which the both ends of the front surface of the unit is fastened by bolts onto the pair of rails provided in the interior of the rack frame, since the whole unit is supported only by the front surface of the unit, the rear side of the unit is likely to hang down. During transportation, when a plurality of units is accommodated in the rack, the rear side of each of the units becomes a free end and unstably shakes in the upward and downward directions, whereby the neighboring units interfere with each other in the upward and downward directions, and such an instable shaking may become a cause of destruction of the units.

According to a method of placing the unit on the angle mount brackets provided in the interior of the rack frame, the hang-down of the rear side of the unit may be prevented, but the angle mount brackets will be required separately, and moreover, since further space for placing the angle mount brackets will be required, the accommodation efficiency of the units becomes poor.

Moreover, due to position unevenness during assembling or due to stress deformation, if the position of the rail in the interior of the rack frame deviates from the correct position, the screw hole on the side of the unit and the screw hole on the side of the rail will not coincide with each other, and consequently, the unit cannot be mounted at the correct position.

Furthermore, because of the additional problem that the space between the pair of rails in the interior of the frame is somewhat wider than the width of the unit, it is difficult to accommodate the unit at the center of the rack frame.

Based on the problems as described above, an object of the present invention is to enable the accommodation of the units in the rack mount correctly in a stable condition.

### Solution to Problem

Therefore, according to a mounting structure of rack-mount unit of the present invention, a unit is accommodated in a rack mount, by loading the unit from a front opening of the rack mount, and by engagement and fastening of at least two fastening holes, formed in the perpendicular direction of flanges extensively provided at the both ends in the lengthwise direction of the front surface of the unit, with a plurality of fastening holes, formed in the perpendicular direction of a pair of rails elongating in the perpendicular direction and disposed on the both sides on the front side in the interior of the rack mount. One end of a plate-shaped part elongating from the flange toward a body side panel of the unit is connected to the flange, and another end of the plate-shaped part is connected to the body side panel, so as to represent a triangle, of which hypotenuse is the plate-shaped part, and of which adjacent side is the body side panel of the unit.

According to the above structure, the one end of the plate-shaped part elongating from the flange toward the body side panel of the unit is connected to the flange, and the other end of the plate-shaped part is connected to the body side panel, whereby a truss structure can be formed in the vicinity of the flange of the unit, substantially representing a right-angled triangle as viewed from the plane surface side, in which, the plate-shaped part is the hypotenuse, and the body side panel of the unit is the adjacent side. Because of the reinforcing effect of the truss structure formed in the vicinity of the flange of the unit, the deformation of the unit in the vicinity of the flange can be prevented, and the shaking of the unit in the upward and downward directions during transportation can be prevented, so as to avoid the interference of units with each other, and therefore, the unit can be accommodated in the rack mount in a stable condition. Moreover, when the unit is installed in the rack mount, since the unit is guided to a desired position through contact of the hypotenuse with each of the rails of the rack mount, the unit can be accommodated at the correct position in the rack mount.

Preferably, with the above structure, the one end of the plate-shaped part may be bent and elongated so as to form a connecting portion parallel to the flange, and the other end of the plate-shaped part may be bent and elongated so as to form a connecting portion parallel to the body side panel of the unit.

With the above structure, a connecting portion at the one end of the plate-shaped part may be provided with at least two fastening parts formed in the perpendicular direction to be engaged with fastening holes of the flange, and the fastening hole may have a wide opening extending in the horizontal direction of the unit.

According to the above structure, since the wide opening extending in the horizontal direction of the unit is provided, when the unit is fastened, the slight movement in the horizontal direction is allowed, whereby the positioning of the unit can be performed easily.

With the above structure, the plate-shaped part may have a flexible property.

According to the above structure, because of the flexible property of the plate-shaped part, the positioning of the unit is performed in a state that the plate-shaped part flexibly becomes in contact with the each of the rails of the rack mount.

With the above structure, the fastening part may be a oblong hole or a recessed groove.

Preferably, with the above structure, the angle formed by the hypotenuse and the adjacent side may be less than 45 degrees.

According to the above structure, the gradient of the plate-shaped part becomes smaller, and the length of the hypotenuse becomes longer, and consequently, when the unit is installed in the rack mount, the positioning of the unit at the center of the rack mount can be performed easily.

According to a rack-mount mounting member for accommodating a unit in a rack mount, a unit is accommodated in the rack mount, by loading the unit from a front opening of the rack mount, and by engagement and fastening of at least two fastening holes, formed in the perpendicular direction of flanges extensively provided at the both ends in the lengthwise direction of the front surface of the unit, with a plurality of fastening holes, formed in the perpendicular direction of a pair of rails elongating in the perpendicular direction and disposed on the both sides on the front side in the interior of the rack mount. The rack-mount mounting member is provided with, a connecting portion, formed by bending and elongating one end of a plate-shaped part having a flexible property to be parallel to the flange, so as to be connected to the flange, and a connecting portion, formed by bending and elongating another end of the plate-shaped part to be parallel to a body side panel of the unit, so as to be connected to the body side panel of the unit. The connecting portion at the one end of the plate-shaped part is provided with at least two fastening parts, each of which having a wide opening extending in the horizontal direction of the unit, so as to be engaged with each of fastening holes of the flange.

When the rack-mount mounting member according to the above structure is used, the one end of the plate-shaped part elongating from the flange toward the body side panel of the unit is connected to the flange, and the other end of the plate-shaped part is connected to the body side panel, whereby a truss structure can be formed in the vicinity of the flange of the unit, substantially representing a right-angled triangle as viewed from the plane surface side, in which, the plate-shaped part is the hypotenuse, and the body side panel of the unit is the adjacent side. Because of the reinforcing effect of the truss structure formed in the vicinity of the flange of the unit, the deformation of the unit in the vicinity of the flange can be prevented, and the shaking of the unit in the upward and downward directions during transportation can be prevented, so as to avoid the interference of units with each other, and therefore, the unit can be accommodated in the rack mount in a stable condition. Moreover, when the unit is installed in the rack mount, since the unit is guided to a desired position through contact of the hypotenuse with each of the rails of the rack mount, the unit can be accommodated at the correct position in the rack mount.

### BRIEF EXPLANATION OF DRAWINGS

FIG. 1 is a perspective view of a unit provided with rack-mount mounting members according to the present invention;

FIG. 2 is a plane view of the unit as shown in FIG. 1;

FIG. 3 is a front view of the unit as shown in FIG. 1;

FIG. 4 is a side view of the unit as shown in FIG. 1;

FIG. 5 is an expanded plane view showing a portion A of the unit as shown in FIG. 1;

FIG. 6 is a perspective view of the rack-mount mounting member according to the present invention;

FIG. 7 is a side view of the rack-mount mounting member as shown in FIG. 6;

FIG. 8 is a plane view of the rack-mount mounting member as shown in FIG. 6;

FIG. 9 is a front view of the rack-mount mounting member as shown in FIG. 6;

FIG. 10 is a perspective view of a mounting structure of rack-mount unit according to the present invention;

FIG. 11 is a perspective view of the mounting structure of rack-mount unit according to the present invention;

FIG. 12 is a partially expanded front view of the mounting structure of rack-mount unit as shown in FIG. 10 and FIG. 11;

FIG. 13 is a view explaining a dynamics model when a unit according to a conventional art is mounted in a state of cantilever beam;

FIG. 14 is a view explaining the internal force applied to each side with reference to the dynamics model shown in FIG. 13;

FIG. 15 is a view explaining the deformation of a unit casing;

FIG. 16 is a view explaining a dynamics model of the mounting structure of rack-mount unit according to the present invention;

FIG. 17 is a view explaining a truss structure formed by disposition of the rack-mount mounting members in the deformation region as shown in FIG. 15;

FIG. 18 is a view explaining the internal forces applied to each side of the truss structure as shown in FIG. 17;

FIG. 19 is a view explaining a dynamics model of the mounting structure of rack-mount unit according to the present invention;

FIG. 20 is a view explaining the internal force applied to each side with reference to the dynamics model shown in FIG. 19;

FIG. 21 is a view explaining a dynamics model of a truss structure on the side surface of the unit according to the mounting structure of rack-mount unit of the present invention;

FIG. 22 is a view explaining the internal force applied to each side of the truss structure as shown in FIG. 21; and

FIG. 23 is a view of a unit placed on angle mount brackets provided in the interior of a rack frame.

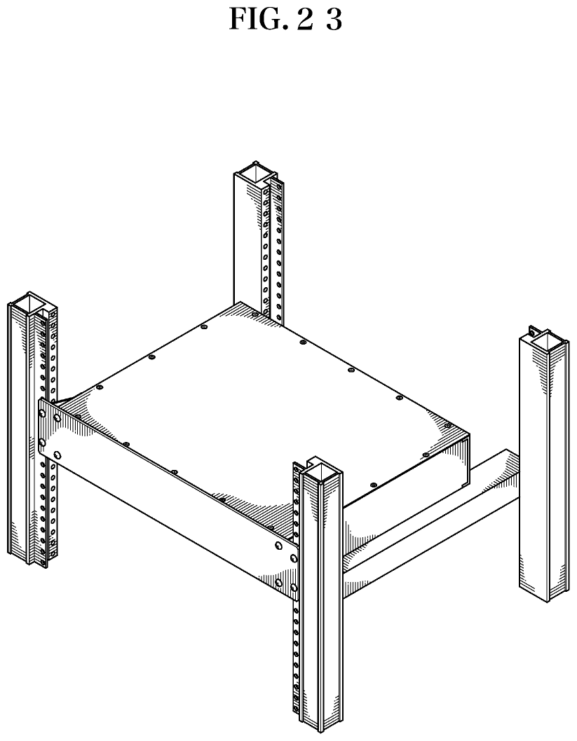

### BEST MODE(S) OF CARRYING OUT INVENTION

Now, an embodiment of the present invention will be explained with reference to the drawings attached hereto.

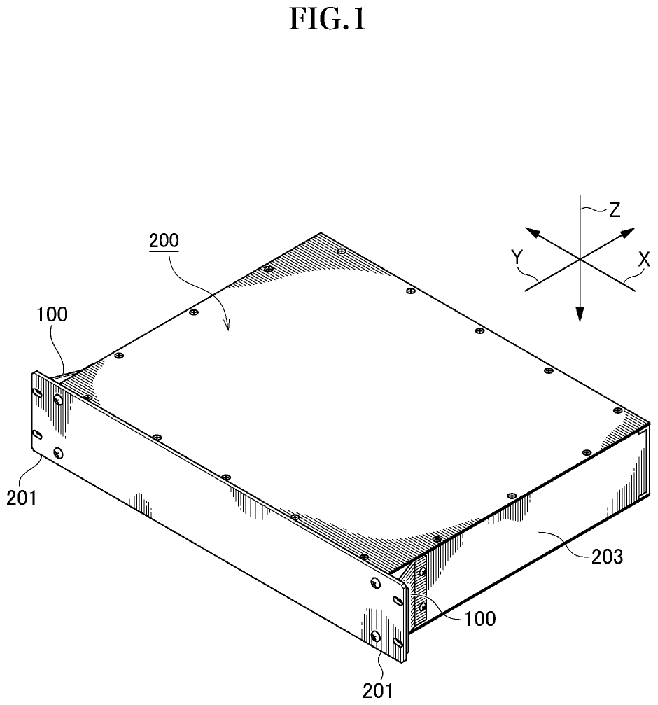

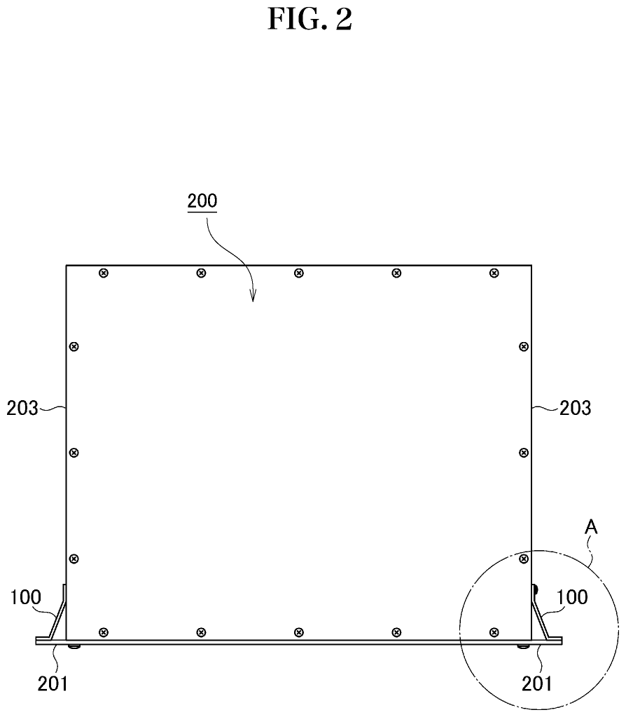

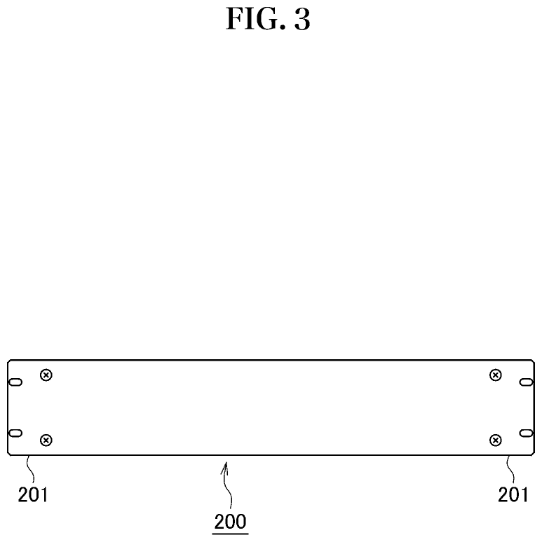

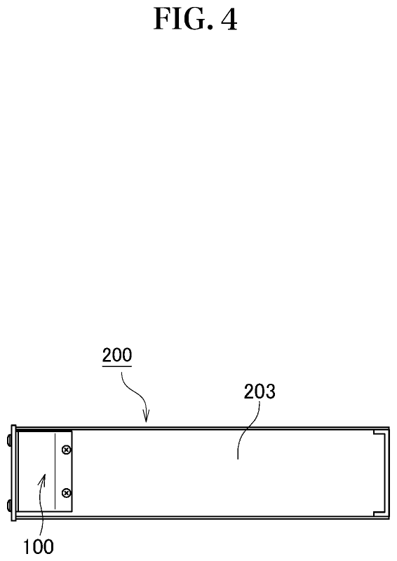

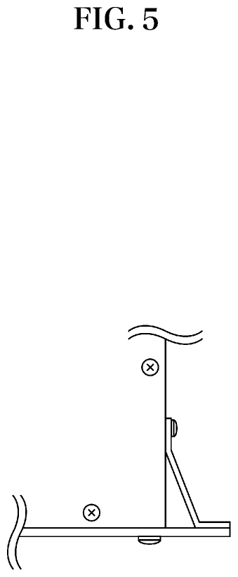

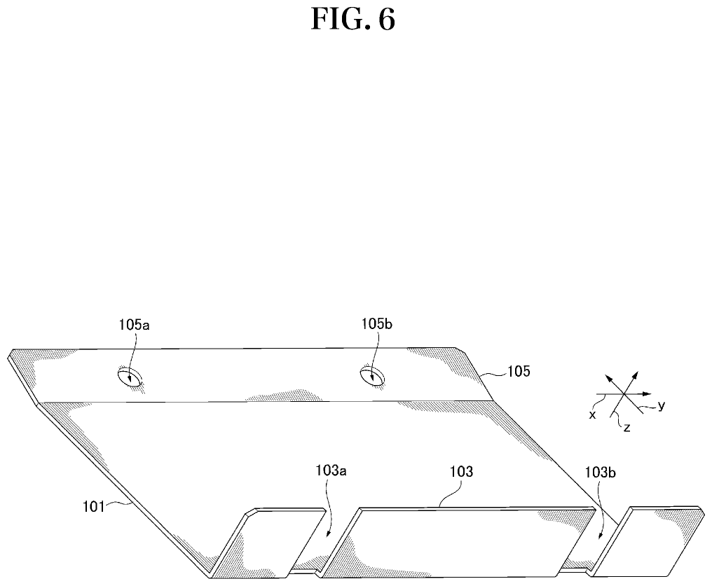

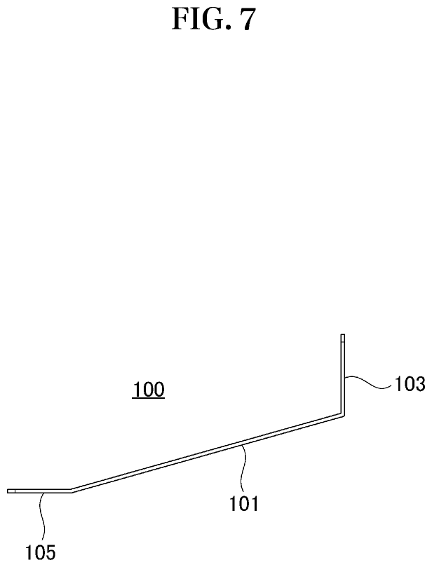

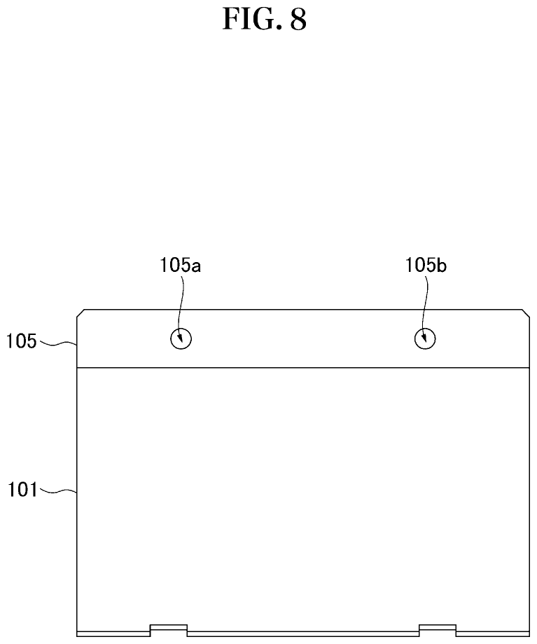

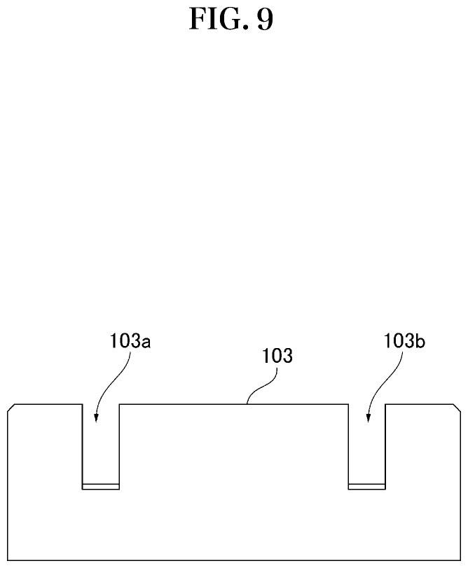

FIG. 1 is a perspective view of a unit 200 provided with rack-mount mounting members 100. In FIG. 1, the direction of an arrow X is to be understood as a view seen from the side surface side. Similarly, the direction of an arrow Y as the view seen from the front surface side, and the direction of an arrow Z as the view seen from the plane surface side. FIG. 2 is a plane view of the unit 200 as shown in FIG. 1; FIG. 3 is a front view of the unit 200 as shown in FIG. 1; FIG. 4 is a side view of the unit 200 as shown in FIG. 1; and FIG. 5 is an expanded plane view of a portion A of the unit 200 as shown in FIG. 1. Moreover, FIG. 6 is a perspective view of the rack-mount mounting member 100. In FIG. 6, the direction of an arrow X is to be understood as a view seen from the side surface side, and similarly, the direction of an arrow Y as the view seen from the front surface side, and the direction of an arrow Z as the view seen from the plane surface side. FIG. 7 is a side view of the rack-mount mounting member 100 as shown in FIG. 6; FIG. 8 is a plane view of the rack-mount mounting member 100 as shown in FIG. 6; and FIG. 9 is a front view of the rack-mount mounting member 100 as shown in FIG. 6.

The rack-mount mounting member 100 is provided in a space between a flange 201, provided at each of both ends in the lengthwise direction of the front surface of the unit 200, and a body side panel 203 of the unit 200, elongating rearwardly from the front surface of the unit 200. With this structure, a connecting portion 103 forming one end of a plate-shaped part 101, is connected to the flange 201, and a connecting portion 105 forming another end of the plate-shaped part 101, is connected to the body side panel 203 of the unit 200, so as to represent substantially a right-angled triangle, in which the plate-shaped part 101 is the hypotenuse, and the body side panel of the unit 200 is the adjacent side.

The rack-mount mounting member 100 is provided with the connecting portion 103 and the connecting portion 105. The connecting portion 103 is formed, by bending one end of the plate-shaped part 101, substantially in the rectangular shape elongating in the lateral direction and having a flexible property, in the direction orthogonal to the lengthwise direction of the plate-shaped part 101 to substantially form a letter “L” as viewed from the side surface side of FIG. 6, and by elongating the one end parallel to the flange 201 so as to be connected to the flange 201. The connecting portion 105 is formed, by bending another end of the plate-shaped part 101 in the direction orthogonal to the lengthwise direction of the plate-shaped part 101 to substantially form a Japanese character “ [symbol] (pronunciation: [he])” as viewed from the side surface side of FIG. 6, and by elongating the other end parallel to the body side panel 203 of the unit 200 so as to be connected to the body side panel 203 of the unit 200. The connecting portion 103 at the one end of the plate-shaped part 101 has two recessed grooves 103a, 103b, formed to be corresponding to the perpendicular direction of the unit 200. Each of the recessed grooves 103a, 103b has a wide opening extending in the horizontal direction of the unit 200, and the recessed grooves 103a, 103b form fastening parts by engagement with the flange 201. The number of the recessed grooves is not limited to two, and three or more recessed grooves may be provided.

The recessed grooves 103a, 103b, formed at the both ends in the lengthwise direction of the connecting portion 103, and two bolt (i.e. fastening) holes formed at the upper and lower positions of the flange 201 of the unit 200, are engaged with each other, and fastened by screwing, etc. The connecting portion 105 is provided with holes 105a, 105b, formed at the both ends in the lengthwise direction of the connecting portion 105. The holes 105a, 105b is engaged with two bolt holes formed at the upper and lower positions of the side body panel 203 of the unit 200, and fastened by adhesion, welding, etc.

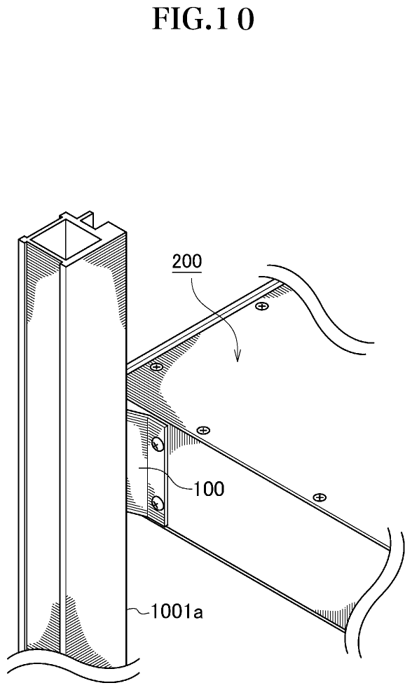

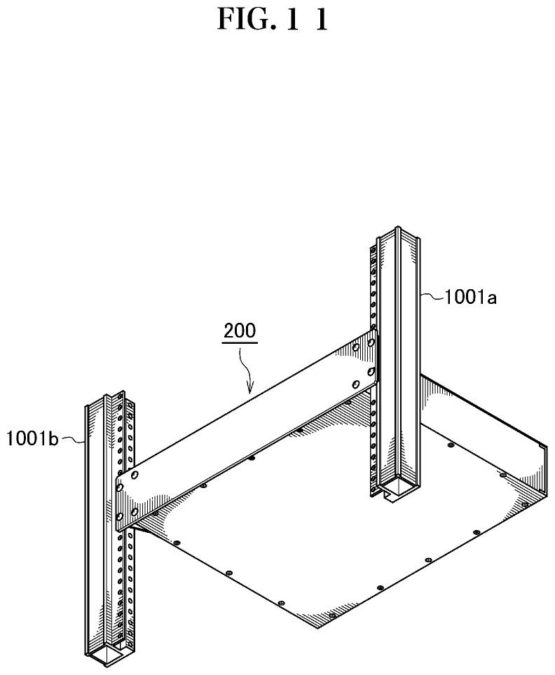

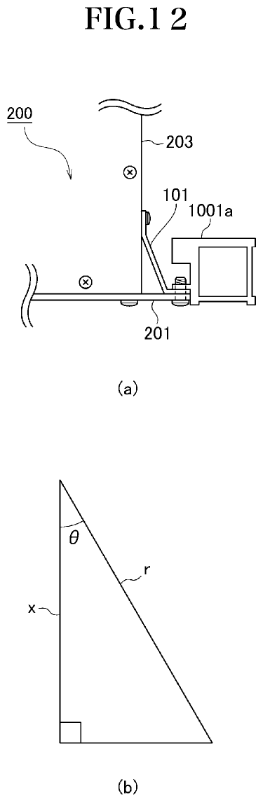

FIG. 10 and FIG. 11 are perspective views of a mounting structure of the rack-mount unit 200, and FIG. 12 is a partially expanded front view of the mounting structure of the rack-mount unit 200 as shown in FIG. 10 and FIG. 11. According to the mounting structure of the rack-mount unit 200, the unit 200 is loaded from a front opening of a rack mount (not shown). The unit 200 has flanges at the both ends of the front surface, each of which is elongating in the lengthwise direction of the front surface, and at least two fastening holes are formed in the perpendicular direction of each flange. On the other hand, a pair of rails 1001a, 1001b, respectively elongating in the perpendicular direction, are disposed on the both sides in the horizontal direction on the front side in the interior of a mount frame of the rack mount, and fastening holes are formed in the perpendicular direction of each of the rails 1001a, 1001b. Thus, the plurality of fastening holes of each of the rails 1001a, 1001b is engaged with the bolt (i.e. fastening) holes formed at the both ends of the front surface of the unit 200, and is fastened by screwing, etc., whereby the unit 200 is accommodated in the rack mount.

As illustrated in FIG. 12 (a), in a state that the unit 200 is fastened to the rail 1001a, a truss is formed substantially in a shape of right-angled triangle as viewed from the plane surface side, in which, the plate-shaped part 101 is the hypotenuse, and the body side panel 203 of the unit 200 is the adjacent side. As illustrated in FIG. 12 (b), when the angle θ formed by the hypotenuse r and the adjacent side x becomes lager, the gradient of the hypotenuse r becomes larger. On the other hand, when the angle θ formed by the hypotenuse r and the adjacent side x becomes smaller, the gradient of the hypotenuse r becomes smaller.

For the purpose of installation of the unit 200 in the rack mount, when the angle θ formed by the hypotenuse r and the adjacent side x is decreased to be less than 45 degrees so as to decrease the gradient, the working efficiency for the installation of the unit 200 in the rack mount improves. This is because, by decreasing the gradient, the length of the plate-shaped part 101 relative to the hypotenuse r becomes longer, and consequently, when the unit 200 is installed in the rack mount, the length of the plate-shaped part 101 in contact with the rail 1001a can be increased. Accordingly, the positioning of the unit 200 to be at the center of the rack mount can be performed easily.

The plate-shaped part 101 of the rack-mount mounting member 100 has a flexible property, and therefore, the positioning of the unit 200 is performed, in a state that the plate-shaped part 101 flexibly becomes in contact with the rails 1001a, 1001b. Furthermore, each of the recessed grooves 103a, 103b, formed in the connecting portion 103 at the one end of the plate-shaped part 101, has the wide opening extending in the lengthwise direction of the unit 200, which allows the slight movement of the rack-mount mounting member 100, which has been fastened to the unit 200, in the horizontal direction. Thus, the positioning of the unit 200 can be performed more easily. Moreover, the recessed grooves 103a, 103b, formed in the connecting portion 103 at the one end of the plate-shaped part 101, are engaged with the two bolt (i.e. fastening) holes, formed at the upper and lower positions of the flange 201 of the unit 200, and are fastened thereto by screwing, etc. Therefore, the connecting portion 103 and the flange 201 of the unit 200 are not integrated with each other, and consequently, the rotative connecting structure such as a hinge can be provided, whereby the occurrence of bending moment may be prevented.

As examples of the plate-shaped part 101 of the rack-mount mounting member 100, rubber (Young's modulus: 1.5-5×10⁻⁴ GPa), aluminum (Young's modulus: 7.03 GPa), iron (Young's modulus: 211.4 GPa), stainless steel (Young's modulus: 215.3 GPa), tungsten (Young's modulus: 534.4 GPa), carbon-fiber reinforced plastic (polyacrylonitrile) (Young's modulus: 588 GPa), carbon-fiber reinforced plastic (pitch) (Young's modulus: 945 GPa), and any other material having the flexible property may be selected. More preferably, any material having Young's modulus between 7.03 GPa-534.4 GPa may be selected.

In addition, other than the change of gradient by increasing the angle θ formed by the hypotenuse and the adjacent side, the angle θ may be increased by bending the connecting portion 103 of the plate-shaped part 101 in a reversed form of a letter “L,” instead of bending substantially in the form of the letter “L” as shown in the drawing.

With reference to the mounting structure of the rack-mount unit as explained above, some considerations from the viewpoint of dynamics will be described.

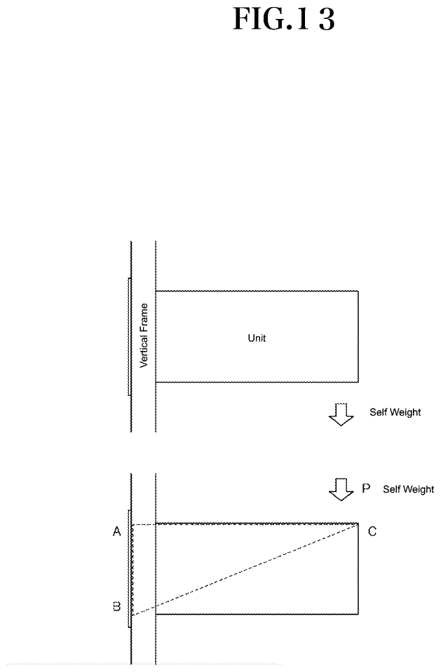

FIG. 13 is a view explaining a dynamics model when a unit according to a conventional art is mounted in a state of cantilever beam, to a pair of rails elongating in the perpendicular direction, disposed at the both ends in the horizontal direction, on the front side in the interior of a rack frame. With reference to the dynamics model as illustrated in FIG. 13, provided that the unit and the rails are rigid bodies, the reaction forces at the supporting points are represented as follows:

$$\begin{matrix}[ Mathematical Formulae 1 ] & \\ \begin{matrix}\sum M = {PL}_{3} - {R}_{BH} {L}_{1} = 0 \\ {R}_{BH} = \frac{{PL}_{3}}{{L}_{1}}\end{matrix} & ( 1 )\end{matrix}$$

$$\begin{matrix}\sum H = {P}_{AH} + {R}_{BH} + P = 0 \\ {R}_{AH} = - P - \frac{{PL}_{3}}{{L}_{1}} = - \frac{P ( {L}_{1} - {L}_{3} )}{{L}_{1}}\end{matrix}$$

$$\begin{matrix}\sum V = P + {P}_{AV} = 0 \\ {R}_{AV} = P\end{matrix}$$

In the Mathematical Formulae (1), each sign represents as below:
M: moment around the point B;
P: self weight;
L₁, L₃: lengths of the respective sides; and
R_{BH}: reaction force in the horizontal direction at the point B.
H: stress in the horizontal direction applied to the truss; and
R_{AH}: reaction force in the horizontal direction at the point A.
V: stress in the perpendicular direction applied to the truss; and
R_{AV}: reaction force in the perpendicular direction applied to the point A.

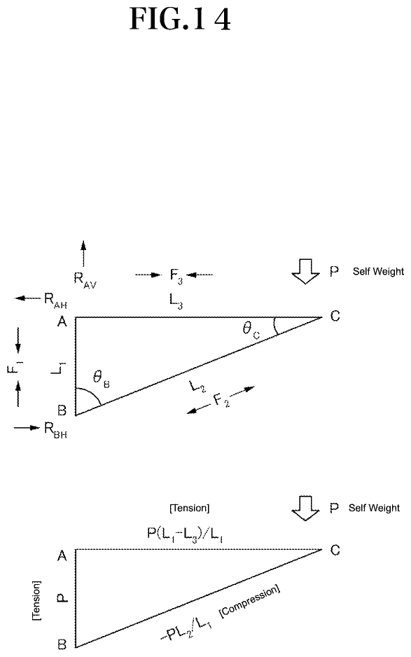

FIG. 14 is a view explaining the internal force applied to each side with reference to the dynamics model shown in FIG. 13. The internal forces as shown in FIG. 14 are represented as follows:

$$\begin{matrix}[ Mathematical Formulae 2 ] & \\ \begin{matrix}\sum H = {F}_{3} - {R}_{AH} = 0 \\ {F}_{3} = {R}_{AH} = \frac{P ( {L}_{1} - {L}_{3} )}{{L}_{1}}\end{matrix} & ( 2 )\end{matrix}$$

$$\begin{matrix}\sum V = {F}_{1} - {R}_{AV} = 0 \\ {F}_{1} = {R}_{AV} = P\end{matrix}$$

$$\begin{matrix}\sum H = {F}_{2} sin {θ}_{B} + {R}_{BH} = 0 \\ {F}_{2} = - \frac{{R}_{BH}}{sin {θ}_{B}} \\ {F}_{2} = - \frac{( \frac{{PL}_{3}}{{L}_{1}} ) {L}_{2}}{{L}_{3}} = - \frac{{PL}_{2}}{{L}_{1}}\end{matrix}$$

In the Mathematical Formulae (2), each sign represents as below:
F₃: internal force applied to L₃;
F₁: internal force applied to L₁; and
F₂: internal force applied to L₂.

Based on the solutions obtained by the above Mathematical formulae, some considerations on the deformation of a unit casing will be described.

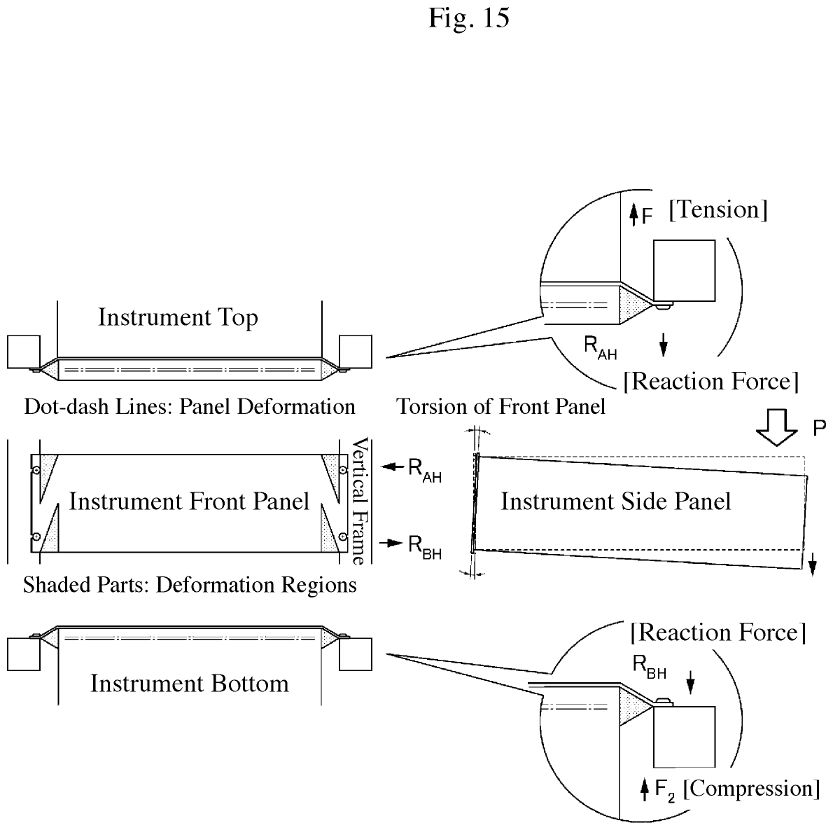

FIG. 15 is a view explaining the deformation of a unit casing. Here, a front panel of a standard-type unit (formed by iron or aluminum having the thickness of 2-3 mm) does not have a sufficient strength, and therefore, attention should be paid to the situation that, on the rear side of the unit being as the free end, the reaction force R_{AH} cannot stand against F₃, which results in the deformation.

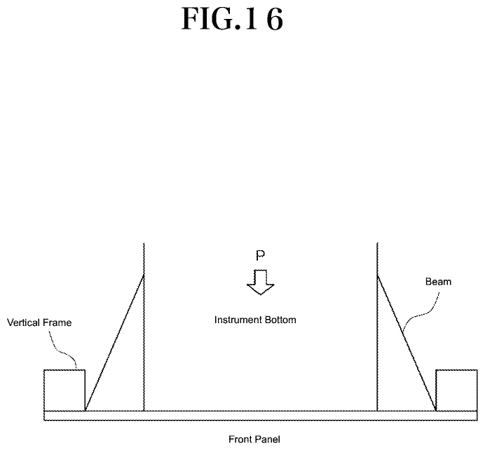

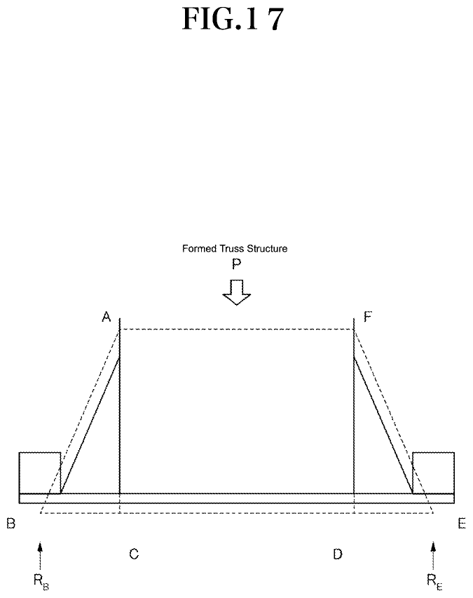

FIG. 16 is a view explaining a dynamics model of the mounting structure of rack-mount unit according to the present invention. For the purpose of easy understanding of calculation, the calculation will be operated on the bottom side of the unit, so that the directions of each force may coincide with those of the general mathematical formula. Also, the bottom surface of the unit casing is considered as a plate material, and the plane stress will not be taken into account. Moreover, because of the symmetrical structure, only one side will be calculated by assuming that BC=DE. FIG. 17 is a view explaining a truss structure formed by disposition of the rack-mount mounting members in the deformation region as shown in FIG. 15. The reaction forces of the thus formed truss structure are represented as follows:

$$\begin{matrix}[ Mathematical Formulae 3 ] & \\ \begin{matrix}\sum M = {PL}_{1} cos {θ}_{B} - {R}_{E} {L}_{2} = 0 \\ {R}_{E} = \frac{{PL}_{1} cos {θ}_{B}}{{L}_{2}} \\ {R}_{E} = \frac{{PL}_{1} ( \frac{{L}_{2}}{{L}_{1}} )}{{L}_{2}} = P\end{matrix} & ( 3 )\end{matrix}$$

$$\begin{matrix}\sum V = {R}_{B} + {R}_{E} - 2 P = 0 \\ {R}_{B} = 2 P - {R}_{E} = P\end{matrix}$$

In the Mathematical Formulae (3), each sign represents as below:
M: moment around the point E;
R_{E}: reaction force at the point E; and
R_{B}: reaction force at the point B.

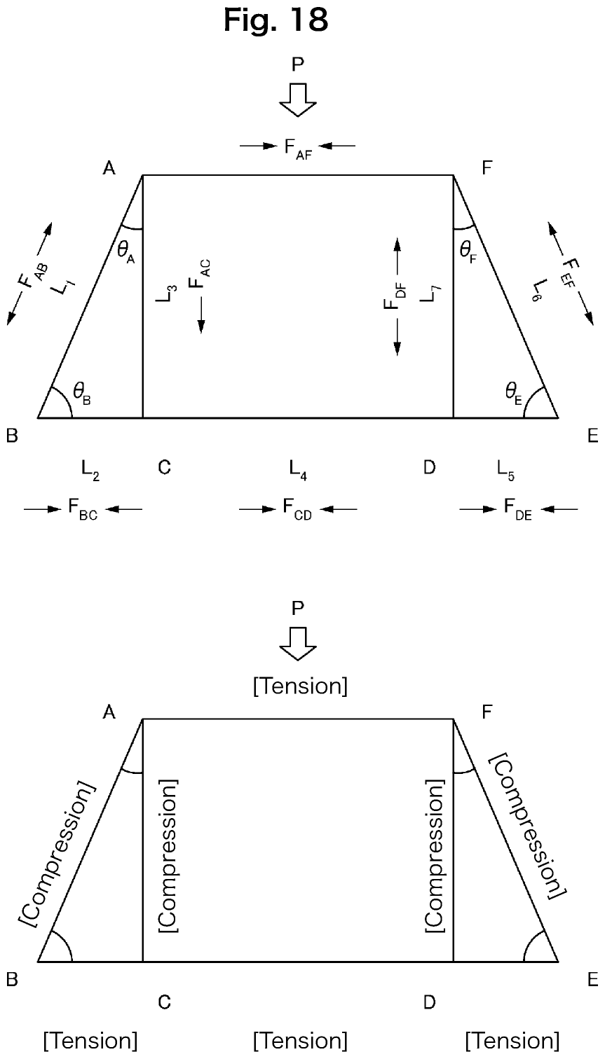

FIG. 18 is a view explaining the internal forces applied to each side of the truss structure as shown in FIG. 17. The internal forces applied to the respective sides are represented as follows:

$$\begin{matrix}[ Mathematical Formulae 4 ] & \\ \begin{matrix}\sum V = {R}_{B} + {F}_{AB} sin {θ}_{A} = 0 & \\ {F}_{AB} = - \frac{{R}_{B}}{sin {θ}_{A}} & \\ {F}_{AB} = - \frac{{PL}_{1}}{{L}_{2}} & ∴ = {F}_{EF} = - \frac{{PL}_{1}}{{L}_{2}}\end{matrix} & ( 4 )\end{matrix}$$

$$\begin{matrix}\sum H = {F}_{BC} + {F}_{AB} cos {θ}_{B} & \\ {F}_{BC} = - {F}_{AB} cos {θ}_{B} & \\ {F}_{BC} = - \frac{( - \frac{{PL}_{1}}{{L}_{2}} ) {L}_{2}}{{L}_{1}} = P & ∴ {F}_{DE} = P\end{matrix}$$

$$\begin{matrix}\sum V = {F}_{A C} - {F}_{AB} sin {θ}_{A} = 0 & \\ {F}_{A C} = \frac{{F}_{AB} {L}_{2}}{{L}_{1}} & \\ {F}_{A C} = \frac{( - \frac{{PL}_{1}}{{L}_{2}} ) {L}_{2}}{{L}_{1}} = - P & ∴ {F}_{DE} = - P\end{matrix}$$

In the Mathematical Formulae (4), each sign represents as below:
V: stress in the perpendicular direction applied to the point B;
F_{AB}: internal force applied to L₁;
H: stress in the horizontal direction applied to the point B; and
F_{BC}: internal force applied to L₂.
V: stress in the perpendicular direction applied to the point A; and
F_{AC}: internal force applied to L₃.

With reference to the considerations as explained above, according to the mounting structure of rack-mount unit of the present invention, the balanced state of internal forces applied to the respective sides can be confirmed. This is because, by releasing the self weight P directly to the rails in the interior of the rack frame, the deformations of ∠ACB and ∠FDE can be prevented.

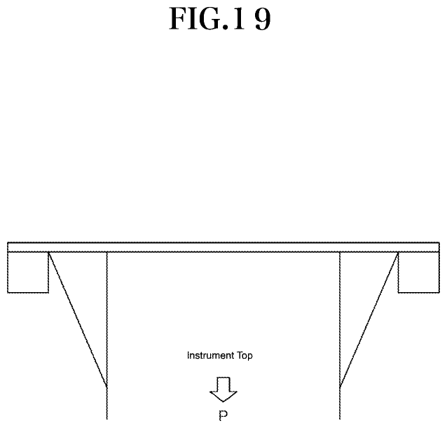

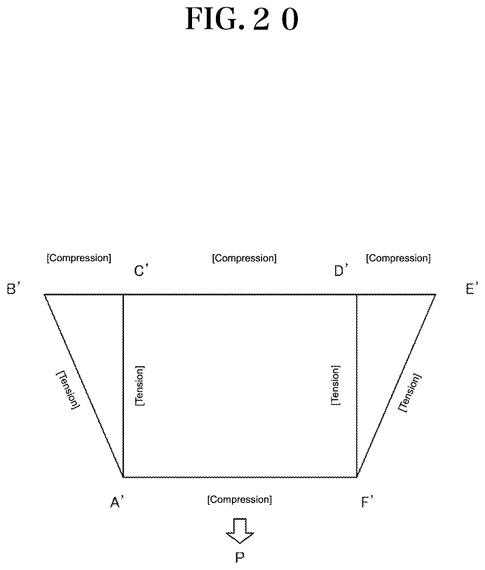

The internal forces applied to the respective sides of the truss structure, as illustrated in FIG. 18, show the internal forces on the bottom surface side of the unit as illustrated in FIG. 16. On the other hand, the internal forces applied to the respective sides of the truss structure, as illustrated in FIG. 20, show the internal forces on the plane surface side of the unit as illustrated in FIG. 19, and the relation between the tension and the compression is represented as the reversed state.

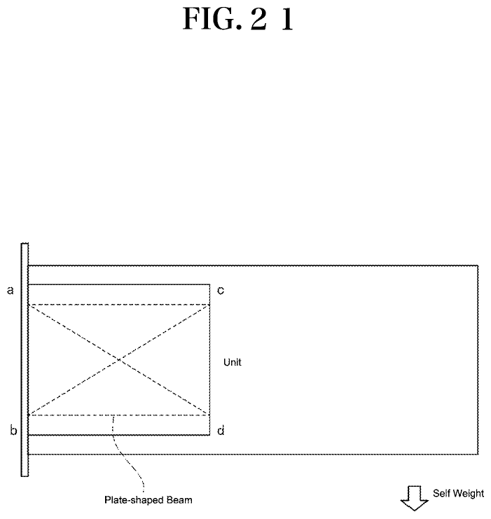

FIG. 21 is a view explaining a dynamics model of a truss structure on the side surface of the unit according to the mounting structure of rack-mount unit of the present invention. Here, provided that the rails in the interior of the rack frame are rigid bodies, the reaction forces at the supporting points are represented as follows:

$$\begin{matrix}[ Mathematical Formulae 5 ] & \\ \begin{matrix}\sum M = {PL}_{3} - {R}_{bh} {L}_{1} = 0 \\ {R}_{bh} = \frac{{PL}_{3}}{{L}_{1}}\end{matrix} & ( 5 )\end{matrix}$$

$$\begin{matrix}\sum H = {R}_{ah} + {R}_{bh} + P = 0 \\ {R}_{ah} = - P - \frac{{PL}_{3}}{{L}_{1}} = - \frac{P ( {L}_{1} - {L}_{3} )}{{L}_{1}}\end{matrix}$$

$$\begin{matrix}\sum V = P - {R}_{av} = 0 \\ {R}_{av} = P\end{matrix}$$

In the Mathematical Formulae (5), each sign represents as below:
M: moment around the point b;
Lₓ: length of each side;
P: self weight; and
R_{bh}: reaction force in the horizontal direction at the point b.
H: stress in the horizontal direction applied to the truss; and
Rₐₕ: reaction force in the horizontal direction at the point a.
V: stress in the perpendicular direction applied to the truss; and
Rₐᵥ: reaction force in the perpendicular direction at the point a.

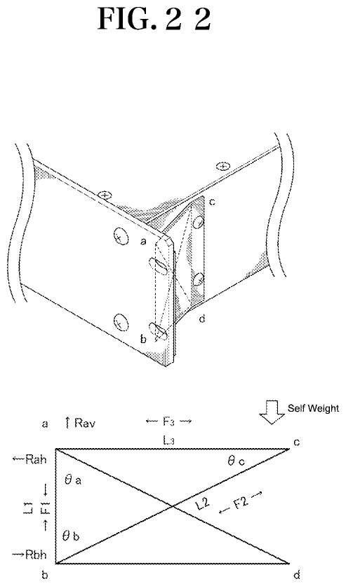

FIG. 22 is a view explaining the internal force applied to each side of the truss structure as shown in FIG. 21. The internal forces applied to the respective sides are represented as follows:

$$\begin{matrix}[ Mathematical Formulae 6 ] & \\ \begin{matrix}\sum H = {F}_{3} - {R}_{ah} = 0 \\ {F}_{3} = {R}_{ah} = \frac{P ( {L}_{1} - {L}_{3} )}{{L}_{1}}\end{matrix} & ( 6 )\end{matrix}$$

$$\begin{matrix}\sum V = {F}_{1} - {R}_{av} = 0 \\ {F}_{1} = {R}_{av} = P\end{matrix}$$

$$\begin{matrix}\sum H = {F}_{2} sin {θ}_{2} + {R}_{bh} = 0 \\ {F}_{2} = - \frac{{R}_{bh}}{sin {θ}_{b}} \\ {F}_{2} = - \frac{( \frac{{PL}_{3}}{{L}_{1}} ) {L}_{2}}{{L}_{3}} = - \frac{{PL}_{2}}{{L}_{1}}\end{matrix}$$

In the Mathematical Formulae (6), each sign represents as below:
F₃: internal force of L₃;
F₁: internal force of L₁; and
F₂: internal force of L₂.

With reference to the considerations as explained above, according to the mounting structure of rack-mount unit of the present invention, the balanced state of internal forces applied to the respective sides can be confirmed. Moreover, with reference to Δ abd, this triangle is similar to Δ abc in a state that the seif weight P is reversed, and consequently, even in the case that the unit shakes in the upward and downward directions, the balanced state of internal forces can be confirmed.

### INDUSTRIAL APPLICABILITY

The present invention can be applied to the mounting of units accommodated in the rack mount.

### EXPLANATION OF REFERENCE SIGNS

100 Rack-mount mounting member
101 Plate-shaped part
103, 105 Connecting portions
103a, 103b Recessed grooves
105a, 105b Holes
200 Unit
203 Body side panel
1001a, 1001b Rails

1. A mounting apparatus having a structure of a rack-mount unit for accommodating a unit in a rack mount, by loading of the unit from a front opening of the rack mount, and by engagement and fastening of at least two fastening holes, formed in a perpendicular direction of flanges extensively provided at both ends in a lengthwise direction of a front surface of the unit, with a plurality of fastening holes, formed in the perpendicular direction of a pair of rails elongating in the perpendicular direction and disposed on the both sides on a front side in an interior of the rack mount, wherein the structure comprising:
a plate-shaped part having one end elongating from a flange toward a body side panel of the unit and being connected to the flange, and another end being connected to the body side panel, and
whereby configured a triangle, of which hypotenuse is the plate-shaped part, and of which adjacent side is the body side panel of the unit.

2. The structure of the rack-mount unit according to claim 1, wherein one end of the plate-shaped part is bent and elongated forming or capable of forming a connecting portion parallel to the flange, and
the other end of the plate-shaped part is bent and elongated forming or capable of forming a connecting portion parallel to the body side panel of the unit.

3. The structure of the rack-mount unit according to claim 1, wherein a connecting portion at one end of the plate-shaped part is provided with at least two fastening parts formed in the perpendicular direction to be engaged with fastening holes of the flange, and the fastening hole has a wide opening extending in a horizontal direction of the unit.

4. The structure of the rack-mount unit according to claim 2, wherein the connecting portion at one end of the plate-shaped part is provided with at least two fastening parts formed in the perpendicular direction to be engaged with fastening holes of the flange, and the fastening hole has a wide opening extending in a horizontal direction of the unit.

5. The structure of the rack-mount unit according to claim 3, wherein the plate-shaped part has a flexible property.

6. The structure of the rack-mount unit according to claim 4, wherein the plate-shaped part has a flexible property.

7. The structure of the rack-mount unit according to claim 3, wherein a fastening part of said at least two fastening parts is an oblong hole.

8. The structure of the rack-mount unit according to claim 4, wherein a fastening part of said at least two fastening parts is an oblong hole.

9. The structure of the rack-mount unit according to claim 3, wherein a fastening part of said at least two fastening parts is a recessed groove.

10. The structure of the rack-mount unit according to claim 4, wherein a fastening part of said at least two fastening parts is a recessed groove.

11. The structure of the rack-mount unit according to claim 3, wherein the angle formed by the hypotenuse and the adjacent side is less than 45 degrees.

12. The structure of the rack-mount unit according to claim 4, wherein the angle formed by the hypotenuse and the adjacent side is less than 45 degrees.

13. A rack-mount mounting member for accommodating a unit in a rack mount, by loading of the unit from a front opening of the rack mount, and by engagement and fastening of at least two fastening holes, formed in a perpendicular direction of flanges extensively provided at both ends in a lengthwise direction of a front surface of the unit, with a plurality of fastening holes, formed in the perpendicular direction of a pair of rails elongating in the perpendicular direction and disposed on both sides on a front side in an interior of the rack mount, wherein the rack-mount mounting member comprising:
a first connecting portion, formed by bending and elongating one end of a plate-shaped part having a flexible property to be parallel to the flange, connectable or connecting to the flange, and
a second connecting portion, formed by bending and elongating another end of the plate-shaped part to be parallel to a body side panel of the unit, connectable or connecting to the body side panel of the unit, wherein,
the first connecting portion at the one end of the plate-shaped part is provided with at least two fastening parts, each of which having a wide opening extending in a horizontal direction of the unit, engageable or engaging with each of fastening holes of the flange.
